(19) United States
(12) Patent Application Publication
(10) Pub. No.: US 2009/0183776 A1
(43) Pub. Date: Jul. 23, 2009

(54) Solar cell, method of manufacturing the same, and method of texturing solar cell

(75) Inventors: Gyeayoung Kwag, Seoul (KR); Younggu Do, Seoul (KR)

Correspondence Address: MCKENNA LONG & ALDRIDGE LLP, 1900 K STREET, NW, WASHINGTON, DC, 20006, US

(73) Assignee: LG ELECTRONICS INC., Seoul (KR)

(21) Appl. No.: 12/318,630

(22) Filed: Jan. 2, 2009

(30) Foreign Application Priority Data
Jan. 3, 2008 (KR) 10-2008-0000809

(51) Int. Cl. H01L 31/00; H01L 21/3105

(52) U.S. Cl. 136/261; 438/694; 257/E21.215

(57) ABSTRACT

A solar cell, a method of manufacturing the solar cell, and a method of texturing the solar cell are provided. The method of texturing the solar cell includes depositing metal particles on a solar cell substrate, and etching the solar cell substrate and forming a plurality of hemisphere-shaped grooves on the solar cell substrate to texture a surface of the solar cell substrate.

This application claims the benefit of Korean Patent Application No. 10-2008-0000809 filed on Jan. 3, 2008, the entire contents of which is hereby incorporated by reference.

### BACKGROUND

1. Field

Embodiments relate to a solar cell, a method of manufacturing the solar cell, and a method of texturing the solar cell.

2. Description of the Related Art

Recently, as existing energy sources such as petroleum and coal are expected to be depleted, interests in alternative energy sources for replacing the existing energy sources are increasing. Among the alternative energy sources, a solar cell has been particularly spotlighted because the solar cell has abundant energy sources and does not cause environmental pollution.

The solar cell is classified into a solar heat cell that generates a vapor required to rotate a turbine using a solar heat and a solar light cell that converts photons into electric energy using properties of a semiconductor. The solar light cell is generally referred to as a solar cell.

The solar cell is divided into a silicon solar cell, a compound semiconductor solar cell, and a tandem solar cell depending on a raw material. The silicon solar cell has been mainly used in a solar cell market.

A general silicon solar cell includes a substrate formed of a p-type silicon semiconductor and an emitter layer formed of an n-type silicon semiconductor. A p-n junction similar to a diode is formed at an interface between the substrate and the emitter layer.

When solar light is incident on the solar cell having the above-described structure, electrons and holes are generated in a silicon semiconductor doped with impurities by a photovoltaic effect. In the emitter layer formed of the n-type silicon semiconductor, electrons are majority carriers, while in the substrate formed of the p-type silicon semiconductor, holes are majority carriers. The electrons and the holes generated by the photovoltaic effect are respectively attracted to the n-type silicon semiconductor and the p-type silicon semiconductor, and then respectively move to an electrode electrically connected to the semiconductor substrate and an electrode electrically connected to the emitter layer. The electrodes are connected to each other using electric wires to thereby obtain an electric power.

A reflectance of the solar light incident on the semiconductor substrate needs to be reduced so as to improve a conversion efficiency of the solar cell. For this, a method for texturing the semiconductor substrate has been used.

In a chemical etching method that has been generally used, a semiconductor substrate is immersed in an etchant, whose an etch rate varies depending on a crystal direction of silicon, and grooves having a depth of several micrometers (μm) are formed on the surface of the semiconductor substrate. Hence, the semiconductor substrate is textured. In case the chemical etching method is used to texture the semiconductor substrate formed of single crystal silicon, it is difficult to reduce the size of a groove formed through a texturing process to the size smaller than a predetermined size. In particular, it is difficult to use the chemical etching method in a process for texturing a semiconductor substrate formed of polycrystalline silicon. Therefore, the chemical etching method is limited to a reduction in the reflectance.

### SUMMARY

Embodiments provide a solar cell capable of increasing its conversion efficiency by reducing a reflectance of solar light, a method of manufacturing the solar cell, and a method of texturing the solar cell.

In one aspect, there is a method of texturing a solar cell comprising depositing metal particles on a solar cell substrate; and etching the solar cell substrate and forming a plurality of hemisphere-shaped grooves on the solar cell substrate to texture a surface of the solar cell substrate.

In another aspect, there is a solar cell comprising a semiconductor substrate of a first conductive type, an emitter layer of a second conductive type different from the first conductive type on the semiconductor substrate, a first electrode electrically connected to the emitter layer, a second electrode electrically connected to the semiconductor substrate, and a plurality of hemisphere-shaped grooves on a light receiving surface of the semiconductor substrate.

In another aspect, there is a method of manufacturing a solar cell comprising providing a semiconductor substrate, forming an emitter layer of a conductive type opposite a conductive type of the semiconductor substrate on the semiconductor substrate, depositing metal particles on the emitter layer, etching the emitter layer and forming a plurality of hemisphere-shaped grooves on the emitter layer to texture a surface of the emitter layer, forming a first electrode electrically connected to the textured emitter layer, and forming a second electrode on the semiconductor substrate.

In another aspect, there is a method of manufacturing a solar cell comprising providing a semiconductor substrate, depositing metal particles on the semiconductor substrate, etching the semiconductor substrate and forming a plurality of hemisphere-shaped grooves on the semiconductor substrate to texture a surface of the semiconductor substrate, forming an emitter layer of a conductive type opposite a conductive type of the semiconductor substrate on the textured semiconductor substrate, forming a first electrode electrically connected to the emitter layer, and forming a second electrode on the semiconductor substrate.

### BRIEF DESCRIPTION OF THE DRAWINGS

The accompany drawings, which are included to provide a further understanding of the invention and are incorporated on and constitute a part of this specification, illustrate embodiments of the invention and together with the description serve to explain the principles of the invention. In the drawings:

FIG. 1 is a partial cross-sectional view of a solar cell according to an exemplary embodiment;

FIGS. 2A to 2D are cross-sectional views sequentially illustrating each of stages in an exemplary method for texturing a solar cell substrate of a solar cell according to an embodiment;

FIG. 3 is a photograph of a solar cell substrate deposited with metal particles taken through a field emission scanning electron microscope (FESEM);

FIG. 4 is a photograph of a textured solar cell substrate taken through an FESEM;

FIGS. 5A to 5H are cross-sectional views sequentially illustrating each of stages in an exemplary method for manufacturing a solar cell according to an embodiment;

FIGS. 6A to 6D are cross-sectional views sequentially illustrating each of stages in another exemplary method for manufacturing a solar cell according to an embodiment; and

FIG. 7 is a graph showing reflectances of semiconductor substrates in application examples 1 to 4 and a comparative example 1.

### DETAILED DESCRIPTION

Reference will now be made in detail embodiments of the invention examples of which are illustrated in the accompanying drawings.

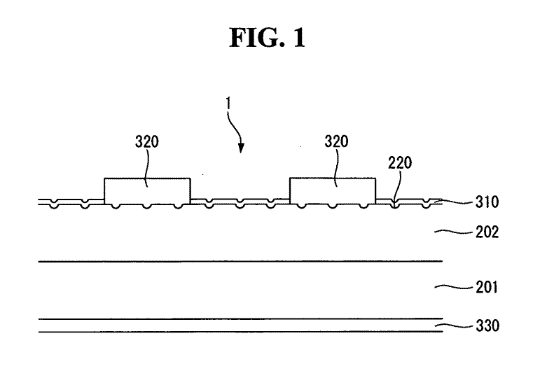

FIG. 1 is a partial cross-sectional view of a solar cell according to an exemplary embodiment.

As shown in FIG. 1, a solar cell 1 according to an exemplary embodiment includes a semiconductor substrate 201, an emitter layer 202 on one surface of the semiconductor substrate 201, an anti-reflection coating layer 310 on the emitter layer 202, a plurality of first electrodes 320 (referred to as a front electrode) electrically connected to the emitter layer 202, and a plurality of second electrodes 330 (referred to as a rear electrode) that are formed on the entire rear surface of the semiconductor substrate 201 to be electrically connected to the semiconductor substrate 201.

In the exemplary embodiment, the semiconductor substrate 201 is formed of first conductive type silicon, for example, p-type silicon. However, the semiconductor substrate 201 may be formed of n-type silicon. In the exemplary embodiment, the semiconductor substrate 201 is formed of polycrystalline silicon. However, the semiconductor substrate 201 may be formed of single crystal silicon. Amorphous silicon or other semiconductor materials may be used for the semiconductor substrate 201.

The emitter layer 202 is formed on the entire upper surface of the semiconductor substrate 201. The emitter layer 202 is formed by diffusing impurities of a second conductive type opposite the first conductive type of the semiconductor substrate 201 on the entire upper surface of the semiconductor substrate 201. Hence, the semiconductor substrate 201 and the emitter layer 202 form a p-n junction. A plurality of fine grooves 220 are formed on the surface of the emitter layer 202 serving as a light receiving surface of the solar cell. Hence, a light reflectance of the upper surface of the emitter layer 202 is reduced. Light is confined inside the solar cell by performing a plurality of incident and reflection operations of light on the fine grooves 220. Hence, a light absorptance increases, and the efficiency of the solar cell 1 is improved.

In the present embodiment, the groove 220 has a hollow hemisphere shape. The groove 220 has a diameter of approximately 100 nm to 500 nm and a depth of approximately 100 nm to 1 μm. Because the semiconductor substrate 201 and the emitter layer 202 form the p-n junction, the emitter layer 202 may be formed of p-type silicon when the semiconductor substrate 201 is formed of n-type silicon.

The emitter layer 202 may be formed by diffusing phosphor (P), arsenic (As), antimony (Sb), etc. on the upper surface of the semiconductor substrate 201.

An anti-reflection layer 310 formed of silicon nitride (SiNx) or silicon oxide (SiO₂) is formed on the entire surface of the emitter layer 202. The anti-reflection layer 310 reduces a reflectance of incident solar light and increases a selectivity of a specific wavelength band, thereby increasing the efficiency of the solar cell. The anti-reflection layer 310 may have a thickness of approximately 70 nm to 80 nm. The anti-reflection layer 310 may be omitted, if necessary.

The plurality of front electrodes 320 are positioned on the anti-reflection layer 310 to be spaced apart from each other at a constant distance. The front electrodes 320 extend in one direction and are electrically connected to the emitter layer 202. The front electrodes 320 are formed of at least one conductive metal material. Examples of the conductive metal material include nickel (Ni), copper (Cu), silver (Ag), aluminum (Al), tin (Sn), zinc (Zn), indium (In), titanium (Ti), gold (Au), and a combination thereof. Other conductive metal materials may be used.

The rear electrodes 330 are formed on the entire rear surface of the semiconductor substrate 201 and electrically connected to the semiconductor substrate 201. The rear electrodes 330 are formed of a conductive metal material. Examples of the conductive metal material include Ni, Cu, Ag, Al, Sn, Zn, In, Ti, Au, and a combination thereof. Other conductive metal materials may be used.

FIG. 1 shows that the textured emitter layer 202 is formed on the upper surface of the solar cell 1 serving as a light receiving surface (i.e., on the upper portion of the semiconductor substrate 201). However, the textured emitter layer 202 may be formed on a lower surface of the solar cell 1. In this case, the emitter layer 202 may have a non-textured flat surface, and the upper surface of the semiconductor substrate 201 may be textured to have the hemisphere-shaped grooves 220.

The solar cell 1 having the above-described structure operates as follows.

When light is incident on the p-n junction of the solar cell 1, electrons and holes are generated in the semiconductor substrate 201 and the emitter layer 202 by light energy. Generally, if light with less energy than band gap energy enters a semiconductor, light energy weakly interacts with electrons within the semiconductor. If light with energy more than or equal to band gap energy enters a semiconductor, electrons within the semiconductor are dislodged from their covalent bonds and electrons or holes are generated. The electrons generated by the light energy move to the n-type emitter layer 202 and then gather on the front electrode 320. The holes generated by the light energy move to the p-type semiconductor substrate 201 and then gather on the rear electrode 330. Then, the front electrode 320 and the rear electrode 330 are connected to each other using electric wires, and thus a current flows between the electrodes 320 and 330. The current is used as an electric power.

Because in the solar cell 1 according to the exemplary embodiment, the emitter layer 202 has a textured surface having the grooves 220 with a diameter of approximately 100 nm to 500 nm and a depth of approximately 100 nm to 1 μm, an absorptance of incident light increases and a reflectance of the incident light decreases.

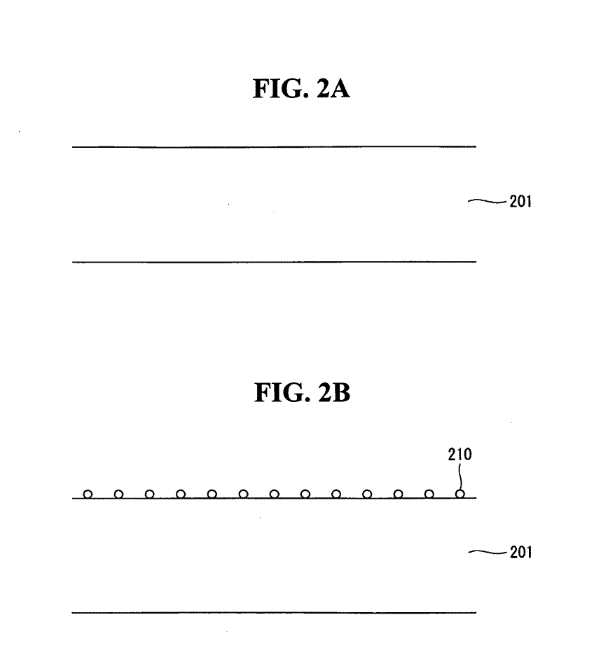

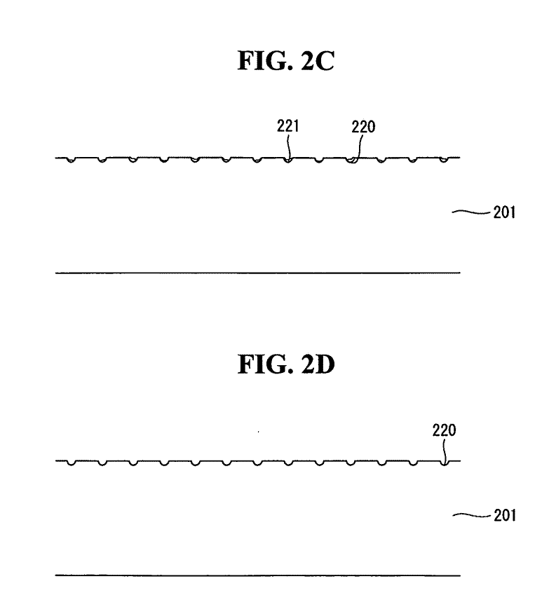

An exemplary method of texturing a solar cell substrate having fine grooves will be described below with reference to FIGS. 2A to 2D, 3 and 4.

FIGS. 2A to 2D are cross-sectional views sequentially illustrating each of stages in an exemplary method of texturing a solar cell substrate.

As shown in FIG. 2A, a solar cell substrate 201 formed of silicon, etc. is provided.

Then, as shown in FIG. 2B, metal particles 210 are deposited on the solar cell substrate 201. Various methods such as a sputtering method may be used to deposit metal particles 210. The metal particles 210 are deposited on the solar cell substrate 201 in island form.

More specifically, in a process for depositing the metal particles 210 using the sputtering method, argon (Ar) gas being an inert gas is injected into a vacuum chamber in a state where the solar cell substrate 201 is positioned inside the vacuum chamber of a sputtering equipment (not shown), and at the same time, a DC power is applied to a target to which the metal particles 210 is emitted. Hence, plasma is generated between the solar cell substrate 201 and the target. Subsequently, the Ar gas is positively ionized by a high DC current resulting from the plasma, and the Ar positive ions are negatively accelerated by a DC current to collide with a surface of the target. The collision allows the metal particles 210 used as a material for forming the target to exchange momentum with the Ar positive ions by a perfectly elastic collision and to be emitted to the outside. The emitted metal particles 210 are deposited on the solar cell substrate 201.

In the process for depositing the metal particles 210 using the sputtering method, a vacuum state of the sputtering equipment, a magnitude of a plasma current, a voltage magnitude between electrodes, a constant depending on the metal particles 210, a deposition time, etc. need to be considered. The above variables to be considered may be substituted for the following Equation 1 to calculate a thickness of a film formed by depositing the metal particles 210.

D=K×I×V×t [Equation 1]

In the above Equation 1, D is a thickness of a film formed by depositing the metal particles 210 (unit: Å), K is a constant depending on the metal particles 210, I is a magnitude of a plasma current, V is a voltage magnitude between electrodes, and t is a deposition time.

According to the above Equation 1, the deposition thickness D of the metal particles 210 is linearly proportional to the deposition time t. Accordingly, it may be preferable that the metal particles 210 are deposited in island form, so as to minimize a damage of the solar cell substrate 201 resulting from the metal particles 210. The deposition of the metal particles 210 in island form is performed by adjusting the deposition time t at a minimum electric power capable of generating the plasma. The deposition time t may be adjusted within a range between 10 sec and 30 sec.

The metal particles 210 may be formed of one of Au, Ag, Cu, Pt, and Pd or a combination thereof. A diameter of the metal particle 210 may be approximately 10 nm to 30 nm.

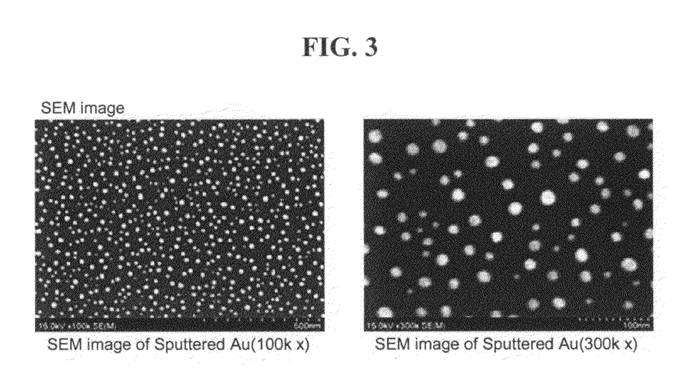

FIG. 3 is a photograph of the solar cell substrate deposited with the metal particles taken through a field emission scanning electron microscope (FESEM).

In FIG. 3, white particles indicate the metal particles 210 formed of Au having a diameter of 10 nm to 30 nm, and a dark portion indicates the surface of the solar cell substrate 201. It could be seen from FIG. 3 that the metal particles 210 were randomly deposited on the surface of the solar cell substrate 201 in island form.

After a process for depositing the metal particles 210 is completed, as shown in FIG. 2C, the solar cell substrate 201 is etched in a state where the metal particles 210 have been deposited. Hence, an upper portion of the solar cell substrate 201 is textured by non-uniformly forming fine hemisphere-shaped grooves 220 on the solar cell substrate 201.

If the solar cell substrate 201 is wet etched, an etch rate of a deposit portion of the substrate 201 deposited with the metal particles 210 is greater than an etch rate of a non-deposit portion of the substrate 201 because of the metal particles 210 serving as a catalyst. Accordingly, the fine hemisphere-shaped grooves 220 are formed on the deposit portion of the substrate 201 through a wet etching process, and an uneven pattern is formed on the surface of the solar cell substrate 201.

The following Reaction Formula 1 indicates an exemplary reaction mechanism of a catalytic action of the metal particles 210 through the wet etching process.

[Reaction Formula 1]

Cathodic Reaction (Metal Particles)

H₂O₂+2H⁺→2H₂O+2H⁺

2H⁺+2e⁻→H₂

Anodic Reaction (Substrate Surface)

Si+4H⁺+4HF→SiF₄+4H⁺

SiF₄+2HF→H₂SiF₆

Total Reaction

Si+H₂O₂+6HF→2H₂O+H₂SiF₆+H₂

As indicated in the above Reaction Formula 1, as the metal particles 210 are deposited on the surface of the solar cell substrate 201, a production of hydrogen ion (H⁺) dissociated from H₂O₂ accelerates and a production of hydrogen (H₂) decelerates. A high concentration of hydrogen ion (H⁺) speeds up a production of SiF₄ on the surface of the solar cell substrate 201 showing the anodic reaction to increase an etch rate of the surface of the solar cell substrate 201 deposited with the metal particles 210.

In the wet etching process, a wet etchant in which HF, H₂O₂ and H₂O are mixed in a volume ratio of 1:5:10 may be used. A composition ratio of the wet etchant may be adjusted depending on an etch rate of the wet etchant. A depth of the groove 220 may vary depending on the etch rate of the wet etchant to thereby control the reflectance of the solar cell.

A diameter and a depth of groove 220 may vary depending on the size, a deposition thickness, a deposition time, etc. of the metal particles. Therefore, it is possible to form the fine groove 220. Preferably, the groove 220 has a diameter of approximately 100 nm to 500 nm and a depth of approximately 100 nm to 1 μm.

When the wet etching process is performed to form the hemisphere-shaped grooves 220 on the surface of the solar cell substrate 201, a remainder 221 of the metal particles 210 remains around the grooves 220 after the wet etching process. Accordingly, as shown in FIG. 2D, the process for texturing the solar cell substrate 201 is completed by removing the remainder 221 of the metal particles 210 remaining after the wet etching process. An aqueous solution used to remove the remaining metal particles 210 may vary depending on a kind of metal particles 210.

For example, in case the remaining metal particles 210 are formed of Au, an aqueous solution obtained by mixing iodine (I) with potassium iodine (KI) may be used. In case the remaining metal particles 210 are formed of Ag, nitrate-based (NO₃²⁻) aqueous solution may be used. In case the remaining metal particles 210 are formed of Cu, one of bromide-based, chloride-based, nitrate-based, and sulfate-based aqueous solutions, or a mixed aqueous solution thereof may be used. In case the remaining metal particles 210 are formed of Pt or Pd, one of chloride-based and nitrate-based aqueous solutions, or a mixed aqueous solution thereof may be used.

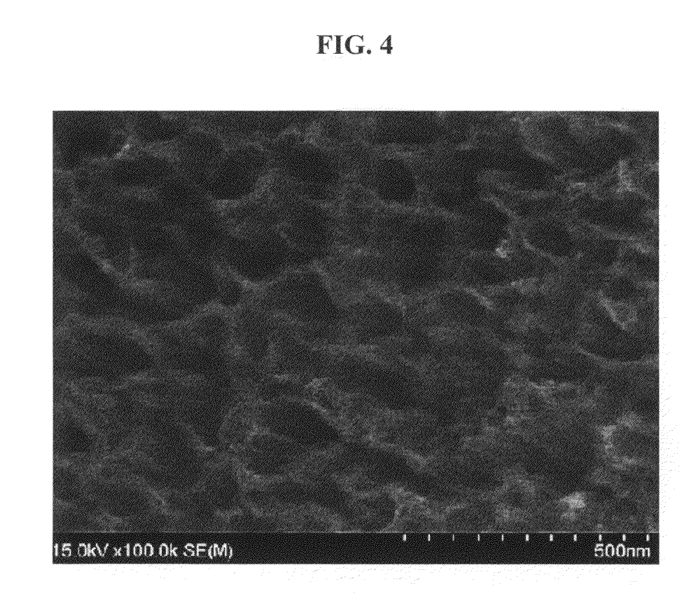

FIG. 4 is a photograph of a textured solar cell substrate taken through an FESEM.

In the exemplary embodiment, it may be preferable that the solar cell substrate 201 is formed of polycrystalline silicon or single crystal silicon. In particular, even if the solar cell substrate 201 uses a polycrystalline silicon substrate incapable of obtaining an excellent texturing effect because it is difficult to perform an anisotropic etching process on the polycrystalline silicon substrate, a reduction width in a reflectance of the solar cell may increase.

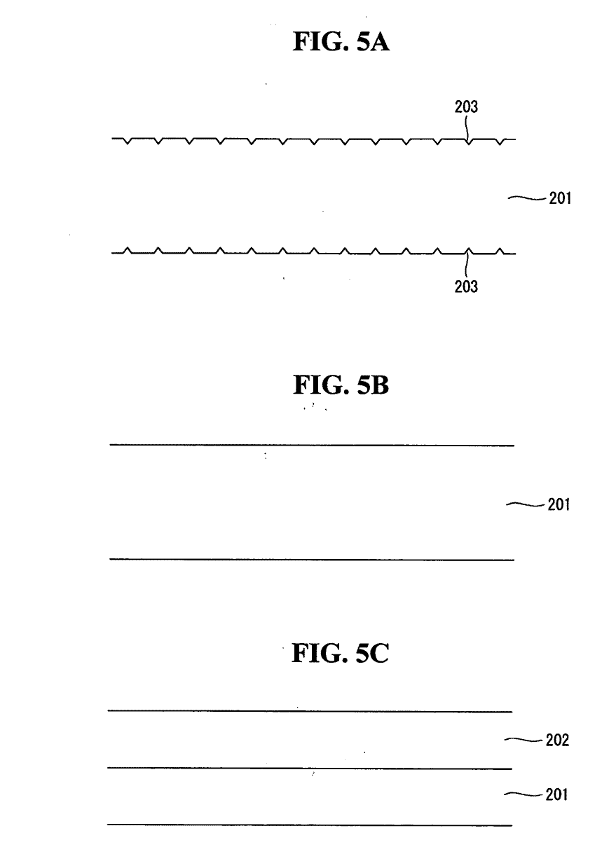

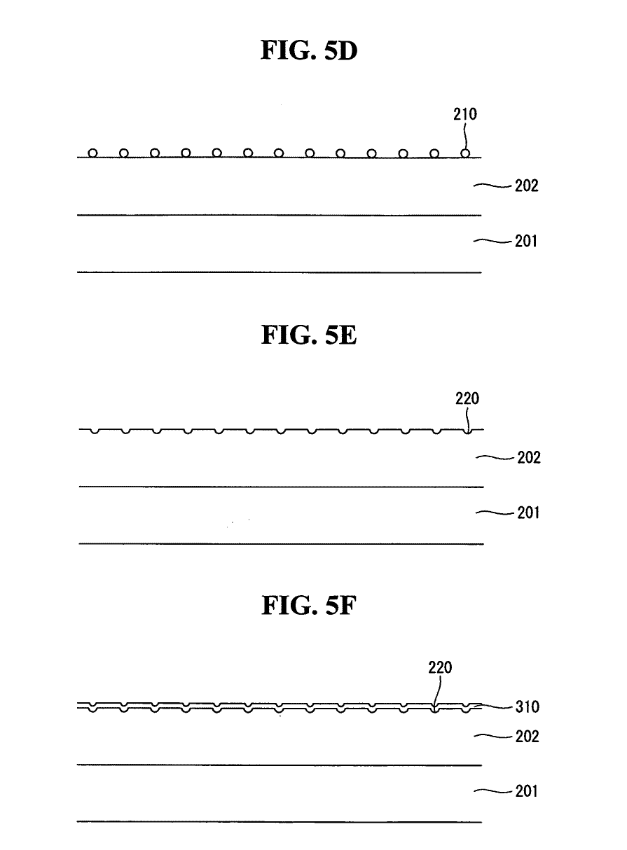

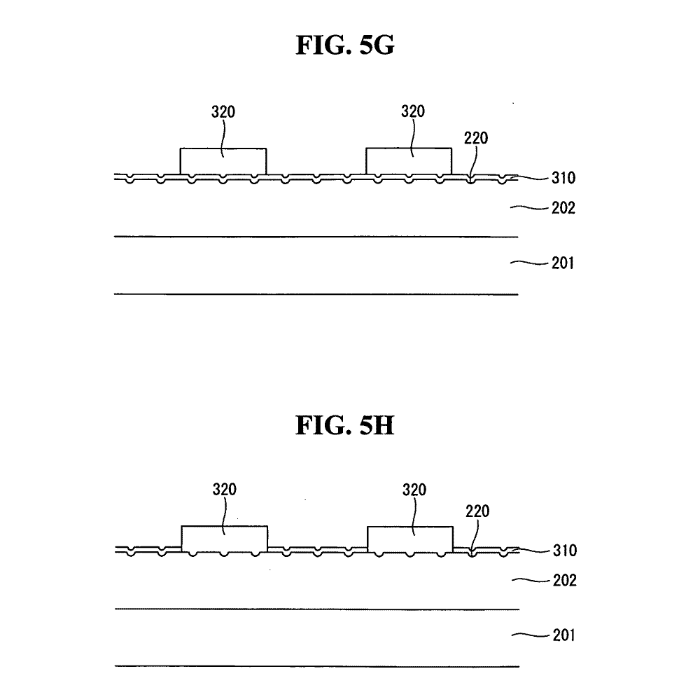

An exemplary method for manufacturing the solar cell to which the exemplary method for texturing the substrate is applied will be described with reference to FIGS. 5A to 5H. Structures and components identical or equivalent to those described in FIGS. 2A to 2D are designated with the same reference numerals in FIGS. 5A to 5H, and a description thereabout is briefly made or is entirely omitted. A description of operations and processes identical or equivalent to those described in FIGS. 2A to 2D is briefly made or is entirely omitted in FIGS. 5A to 5H.

FIGS. 5A to 5H are cross-sectional views sequentially illustrating each of stages in an exemplary method for manufacturing a solar cell according to an embodiment.

As shown in FIG. 5A, a solar cell substrate 201 is provided. Generally, the solar cell substrate 201 is a semiconductor substrate obtained by slicing a semiconductor ingot such as silicon. The semiconductor substrate 201 may be formed of single crystal silicon or polycrystalline silicon. A damage portion 203 is generated on the surface of the semiconductor substrate 201 in a process for slicing the semiconductor ingot. The damage portion 203 may adversely affect the efficiency of the solar cell.

As shown in FIG. 5B, a wet etching process is simultaneously performed on an upper portion and a lower portion of the semiconductor substrate 201 to remove the damage portion 203. The wet etching process for removing the damage portion 203 may be performed by immersing the semiconductor substrate 201 in a container filled with a wet etchant obtained by mixing HF, H₂O₂ and H₂O, for example, for a predetermined period of time.

As shown in FIG. 5C, an emitter layer 202 with a conductive type opposite a conductive type of the semiconductor substrate 201 is formed on the semiconductor substrate 201. Hence, the semiconductor substrate 201 and the emitter layer 202 form a p-n junction.

In the exemplary embodiment, the semiconductor substrate 201 may include p-type and n-type substrates. The p-type semiconductor substrate may be preferable to the n-type semiconductor substrate because of long lifetime and great mobility of minority carriers that are electrons in the p-type semiconductor substrate. The p-type semiconductor substrate may be doped with a group III element such as B, Ga and In. The n-type emitter layer 202 may be formed by doping the p-type semiconductor substrate with a group V element such as P, As and Sb. Hence, a p-n junction may be formed.

After the emitter layer 202 is formed as above, as shown in FIG. 5D, metal particles 210 are deposited on the emitter layer 202 using a sputtering method. The metal particles 210 are deposited on the semiconductor substrate 201 in island form.

After a process for depositing the metal particles 210 is completed, the upper portion of the semiconductor substrate 201 is wet etched in a state where the metal particles 210 have been deposited. Hence, fine grooves 220 are non-uniformly formed on the upper portion of the semiconductor substrate 201, and the surface of the semiconductor substrate 201 is textured as shown in FIG. 5E. The grooves 220 are formed on a deposit portion of the metal particles 210. As described above, because an etch rate of a deposit portion of the substrate 201 deposited with the metal particles 210 is greater than an etch rate of a non-deposit portion of the substrate 201 because of the metal particles 210 serving as a catalyst, it is possible to texture the surface of the emitter layer 202.

The process for texturing the emitter layer 201 is completed by removing the metal particles 210 remaining after the wet etching process. As described above, an aqueous solution used to remove the remaining metal particles 210 may vary depending on a kind of metal particles 210.

As above, as the grooves 220 having a diameter of approximately 100 nm to 500 nm and a depth of approximately 100 nm to 1 μm are formed on the surface of the emitter layer 202 using the metal particles 210, an absorptance of light incident on the emitter layer 202 increases and a reflectance of the light decreases. Hence, the efficiency of the solar cell is improved. In this case, a ratio of the diameter to the depth of the groove is approximately 0.5 to 2. Because the depth of the groove 220 produced through the texturing process is adjusted depending on a deposition time, the groove 220 having a proper depth depending on the size of the solar cell may be formed. Hence, the efficiency of the solar cell is improved.

Then, as shown in FIG. 5F, an anti-reflection layer 310 is formed on the entire surface of the emitter layer 202. The anti-reflection layer 310 may be formed through a chemical vapor deposition (CVD) method such as a plasma enhanced CVD (PECVD) method or a sputtering method using silicon nitride (SiNx) or silicon oxide (SiO₂). The anti-reflection layer 310 may have a single-layered structure or a multi-layered structure including at least two layers each having a different physical property.

Then, a metal paste is printed on the anti-reflection layer 310 using a screen printing method to form front electrodes 320 that are spaced apart from each other at a constant distance and extend in one direction (FIG. 5G). Subsequently, as shown in FIG. 5H, drying and firing processes are performed to electrically connect the front electrodes 320 to the emitter layer 202. The metal paste may be formed of at least one conductive metal material selected from the group consisting of Ni, Cu, Ag, Al, Sn, Zn, In, Ti, Au, and a combination thereof.

The front electrode 320 may be formed using a plating method, a sputtering method, a physical vapor deposition (PVD) method such as an electron beam evaporation method, etc.

After the front electrodes 320 are formed, rear electrodes 330 (refer to FIG. 1) are formed on another surface of the semiconductor substrate 202. A paste including the same conductive material as the front electrode 320 is coated on the semiconductor substrate 202 using a screen printing method, and then drying and firing processes are performed to form the rear electrodes 330. The rear electrodes 330 may be formed using a plating method, a sputtering method, a PVD method such as an electron beam evaporation method, etc.

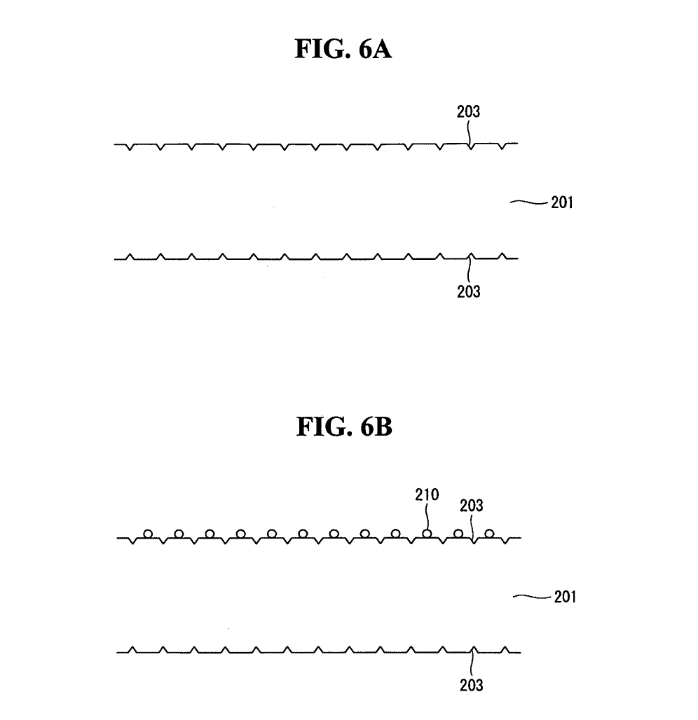

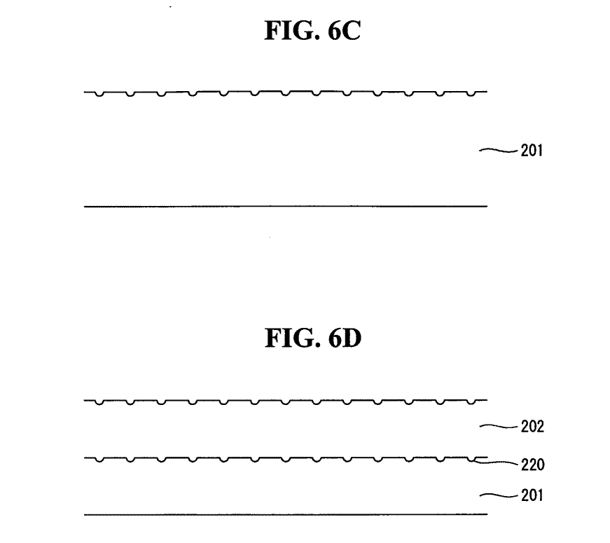

FIGS. 6A to 6D are cross-sectional views sequentially illustrating each of stages in another exemplary method for manufacturing a solar cell according to an embodiment. Structures and components identical or equivalent to those described in FIGS. 2A to 2D are designated with the same reference numerals in FIGS. 6A to 6D, and a description thereabout is briefly made or is entirely omitted. A description of operations and processes identical or equivalent to those described in FIGS. 5A to 5H is briefly made, or is entirely omitted in FIGS. 6A to 6D.

As shown in FIG. 6A, a slicing process is performed on a semiconductor ingot such as silicon to provide a semiconductor substrate 201 serving as a solar cell substrate.

Subsequently, as shown in FIG. 6B, metal particles 210 are deposited on the semiconductor substrate 201 in island form using a sputtering method.

Subsequently, as shown in FIG. 6C, a wet etching process is simultaneously performed on an upper portion and a lower portion of the semiconductor substrate 201 in a state where the metal particles 210 have been deposited to remove a damage portion 203 remaining on the upper portion and the lower portion of the semiconductor substrate 201. At the same time, the upper portion of the semiconductor substrate 201 is textured by forming grooves 220 with a uniform depth on the upper portion of the semiconductor substrate 201.

As described above with reference FIGS. 5A to 5H, a shape of the groove 220 is a hemisphere, the groove 220 has a diameter of approximately 100 nm to 500 nm and a depth of approximately 100 nm to 1 μm, and a ratio of the diameter to the depth of the groove 220 is approximately 0.5 to 2. The depth of the groove 220 may be adjusted depending on a deposition time. After a removal of a damage portion 203 of the semiconductor substrate 201 and a texturing process are completed, the remaining metal particles 210 after the wet etching process are removed. Hence, the upper portion of the semiconductor substrate 201 is textured. Since a process for removing the remaining metal particles 210 is described above, a further description may be entirely omitted.

As shown in FIG. 6D, impurities (for example, n-type impurities) of a conductive type opposite a conductive type of the semiconductor substrate 201 are injected on the textured semiconductor substrate 201 to form an emitter layer 202. As described above, the n-type emitter layer 202 may be formed by doping the semiconductor substrate 201 with a group V element such as P, As and Sb. Hence, a p-n junction is formed.

As described above with reference FIGS. 5F to 5H and FIG. 1, an anti-reflection layer 310, front electrodes 320, and rear electrodes 330 are sequentially formed to complete the solar cell.

In the present embodiment, an absorptance of light incident on the emitter layer 202 increases, and a reflectance of the light decreases. Hence, the efficiency of the solar cell is improved. Further, because a process for removing the damage portion 203 of the semiconductor substrate 201 and a process for texturing the semiconductor substrate 201 are simultaneously performed, a process for manufacturing the solar cell may be simplified.

Application examples will be described below as an example so as to specifically explain the embodiments. The application examples may, however, be embodied in many different forms and should not be construed as being limited to the application examples set forth herein.

### Application Example 1

First, a substrate formed of p-type polycrystalline silicon, from which a damage portion resulting from a slicing process was removed through a saw damage etching process, was provided. The size of the substrate was 4×4 cm. Then, the substrate was deposited with metal particles using a Cressington sputter coater 108 manufactured by Cressington Co., Ltd. The metal particles used were formed of Au, and a constant depending on Au was 0.07. The metal particles were deposited under condition that a voltage between electrodes, a plasma current, a vacuum degree, and a deposition time were set at 1 kV, 1.3 mA, 0.8 mbar, and 10 sec to 30 sec, respectively. Subsequently, the substrate deposited with the metal particles was immersed in a wet etchant obtained by mixing HF, H₂O₂ and H₂O in a volume ratio of 1:5:10 for 80 sec and then wet etched. Subsequently, the remaining metal particles on the substrate were removed by immersing the substrate in an aqueous solution obtained by mixing iodine (I) with potassium iodine (KI) for 10 sec.

### Application Example 2

A process for texturing a substrate formed of p-type polycrystalline silicon in an application example 2 was performed under the same conditions as the above application example 1, except that the substrate deposited with metal particles was immersed in a wet etchant obtained by mixing HF, H₂O₂ and H₂O in a volume ratio of 1:5:10 for 100 sec and then wet etched.

### Application Example 3

A process for texturing a substrate formed of p-type polycrystalline silicon in an application example 3 was performed under the same conditions as the above application example 1, except that the substrate deposited with metal particles was immersed in a wet etchant obtained by mixing HF, H₂O₂ and H₂O in a volume ratio of 1:5:10 for 120 sec and then wet etched.

### Application Example 4

A process for texturing a substrate formed of p-type polycrystalline silicon in an application example 4 was performed under the same conditions as the above application example 1, except that the substrate deposited with metal particles was immersed in a wet etchant obtained by mixing HF, H₂O₂ and H₂O in a volume ratio of for 140 sec and then wet etched.

### Comparative Example 1

A substrate formed of p-type polycrystalline silicon, from which a damage portion resulting from a slicing process was removed through a saw damage etching process, was provided. The size of the substrate was 4×4 cm. A process for texturing the substrate was not separately performed.

Reflectance Measurement

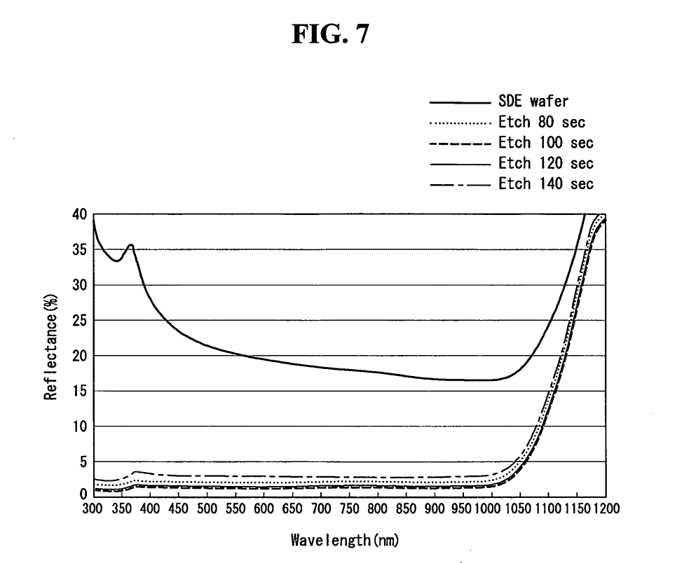

In each of the substrates according to the application examples 1 to 4 and the comparative example 1, a reflectance of a central area with the size of 1×2 cm was measured using a SolidSpec-3700 spectrophotometer manufactured by Shimadzu Corporation. A measurement result was indicated in a graph of FIG. 7. The reflectance was measured at a wavelength capable of contributing for electricity generation, for example, at 300 nm to 1,200 nm. As indicated in the graph of FIG. 7, the reflectances of the substrates were low at most wavelengths between 300 nm and 1200 nm. An average weighted reflectance (AWR) of the substrate was calculated based on the result indicated in FIG. 7 and indicated in the following Table 1.

TABLE 1

| | AWR (%) |
|---|---|
| Comparative Example 1 | 19.23 |
| Application Example 1 | 2.50 |
| Application Example 2 | 1.67 |
| Application Example 3 | 1.78 |
| Application Example 4 | 3.39 |

As indicated in the above Table 1, while the AWR in the comparative example 1 corresponding to the related art was approximately 19%, the AWR in the application examples 1 to 4 corresponding to the embodiments was approximately 1 to 3%. It can be seen from Table 1 that the method for texturing the solar cell greatly contributes to a reduction in the light reflectance.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of texturing a solar cell comprising:
depositing metal particles on a solar cell substrate; and
etching the solar cell substrate and forming a plurality of hemisphere-shaped grooves on the solar cell substrate to texture a surface of the solar cell substrate.

2. The method of claim 1, wherein the solar cell substrate is formed of single crystal silicon or polycrystalline silicon.

3. The method of claim 1, wherein texturing the surface of the solar cell substrate includes etching an upper portion of the solar cell substrate using a wet etchant obtained by mixing HF, H₂O₂ and H₂O.

4. The method of claim 3, wherein texturing the surface of the solar cell substrate includes forming the plurality of grooves on a portion of the solar cell substrate corresponding to a deposition location of the metal particles.

5. The method of claim 4, wherein texturing the surface of the solar cell substrate includes adjusting a composition ratio of the wet etchant to adjust a depth of the groove.

6. The method of claim 1, wherein the metal particles are deposited in island form.

7. The method of claim 6, wherein depositing the metal particles is performed by a sputtering method.

8. The method of claim 6, wherein depositing the metal particles includes adjusting a deposition time of the metal particles at a minimum electric power generating plasma to deposit the metal particles in island form.

9. The method of claim 8, wherein the deposition time of the metal particles is 10 sec to 30 sec.

10. The method of claim 1, wherein the metal particles have a diameter of approximately 10 nm to 30 nm.

11. The method of claim 1, wherein the metal particles are formed of one of gold (Au), silver (Ag), copper (Cu), platinum (Pt), and palladium (Pd) or a combination thereof.

12. The method of claim 1, further comprising, after etching the solar cell substrate, removing the metal particles remaining on the solar cell substrate.

13. The method of claim 12, wherein removing the metal particles is performed by using an aqueous solution obtained by mixing iodine (I) with potassium iodine (KI) in case the remaining metal particles are formed of Au,
wherein removing the metal particles is performed by nitrate-based (NO₃²⁻) aqueous solution in case the remaining metal particles are formed of Ag,
wherein removing the metal particles is performed by one of bromide-based, chloride-based, nitrate-based, and sulfate-based aqueous solutions, or a mixed aqueous solution thereof in case the remaining metal particles are formed of Cu,
wherein removing the metal particles is performed by one of chloride-based and nitrate-based aqueous solutions, or a mixed aqueous solution thereof in case the remaining metal particles are formed of Pt or Pd.

14. The method of claim 1, wherein texturing the upper portion of the solar cell substrate and removing a damage portion remaining on the solar cell substrate are simultaneously performed.

15. A solar cell comprising:
a semiconductor substrate of a first conductive type;
an emitter layer of a second conductive type different from the first conductive type on the semiconductor substrate;
a first electrode electrically connected to the emitter layer;
a second electrode electrically connected to the semiconductor substrate; and
a plurality of hemisphere-shaped grooves on a light receiving surface of the semiconductor substrate.

16. The solar cell of claim 15, wherein the grooves are formed on the light receiving surface of the semiconductor substrate or a surface of the emitter layer on the light receiving surface of the semiconductor substrate.

17. The solar cell of claim 15, wherein the grooves have a diameter of approximately 100 nm to 500 nm.

18. The solar cell of claim 15, wherein the grooves have a depth of approximately 100 nm to 1 μm.

19. The solar cell of claim 15, further comprising an anti-reflection layer between the first electrode and the emitter layer.

20. The solar cell of claim 15, wherein the semiconductor substrate is formed of single crystal silicon or polycrystalline silicon.

21. A method of manufacturing a solar cell comprising;
providing a semiconductor substrate;
forming an emitter layer of a conductive type opposite a conductive type of the semiconductor substrate on the semiconductor substrate;
depositing metal particles on the emitter layer;
etching the emitter layer and forming a plurality of hemisphere-shaped grooves on the emitter layer to texture a surface of the emitter layer;
forming a first electrode electrically connected to the textured emitter layer; and
forming a second electrode on the semiconductor substrate.

22. The method of claim 21, wherein the semiconductor substrate is formed of single crystal silicon or polycrystalline silicon.

23. The method of claim 21, wherein texturing the surface of the emitter layer includes etching an upper portion of the emitter layer using a wet etchant obtained by mixing HF, H₂O₂ and H₂O.

24. The method of claim 23, wherein texturing the surface of the emitter layer includes forming the plurality of grooves on a portion of the emitter layer corresponding to a deposition location of the metal particles.

25. The method of claim 24, wherein texturing the surface of the emitter layer includes adjusting a composition ratio of the wet etchant to adjust a depth of the groove.

26. The method of claim 21, wherein the metal particles are deposited in island form.

27. The method of claim 26, wherein depositing the metal particles includes adjusting a deposition time of the metal particles at a minimum electric power generating plasma to deposit the metal particles in island form.

28. The method of claim 27, wherein the deposition time of the metal particles is 10 sec to 30 sec.

29. The method of claim 21, wherein the metal particles have a diameter of approximately 10 nm to 30 nm.

30. The method of claim 21, wherein the metal particles are formed of one of gold (Au), silver (Ag), copper (Cu), platinum (Pt), and palladium (Pd) or a combination thereof.

31. The method of claim 21, further comprising removing the metal particles remaining on the emitter layer.

32. The method of claim 31, wherein removing the metal particles is performed by using an aqueous solution obtained by mixing iodine (I) with potassium iodine (KI) in case the remaining metal particles are formed of Au,
wherein removing the metal particles is performed by using nitrate-based (NO₃²⁻) aqueous solution in case the remaining metal particles are formed of Ag,
wherein removing the metal particles is performed by using one of bromide-based, chloride-based, nitrate-based, and sulfate-based aqueous solutions, or a mixed aqueous solution thereof in case the remaining metal particles are formed of Cu,
wherein removing the metal particles is performed by using one of chloride-based and nitrate-based aqueous solutions, or a mixed aqueous solution thereof in case the remaining metal particles are formed of Pt or Pd.

33. The method of claim 21, further comprising, before forming the emitter layer, etching an upper portion and a lower portion of the semiconductor substrate to remove a damage portion remaining on the semiconductor substrate.

34. A method of manufacturing a solar cell comprising;
providing a semiconductor substrate;
depositing metal particles on the semiconductor substrate;
etching the semiconductor substrate and forming a plurality of hemisphere-shaped grooves on the semiconductor substrate to texture a surface of the semiconductor substrate;
forming an emitter layer of a conductive type opposite a conductive type of the semiconductor substrate on the textured semiconductor substrate;
forming a first electrode electrically connected to the emitter layer; and
forming a second electrode on the semiconductor substrate.

35. The method of claim 34, wherein texturing the surface of the semiconductor substrate and removing a damage portion remaining on an upper portion and a lower portion of the semiconductor substrate are simultaneously performed.

36. The method of claim 34, wherein texturing the surface of the semiconductor substrate includes etching an upper portion of the semiconductor substrate using a wet etchant obtained by mixing HF, H₂O₂ and H₂O.

37. The method of claim 36, wherein texturing the surface of the semiconductor substrate includes forming the plurality of grooves on a portion of the semiconductor substrate corresponding to a deposition location of the metal particles.

38. The method of claim 36, wherein texturing the surface of the semiconductor substrate includes adjusting a composition ratio of the wet etchant to adjust a depth of the groove.

39. The method of claim 34, wherein the metal particles are deposited in island form.

40. The method of claim 39, wherein the metal particles have a diameter of approximately 10 nm to 30 nm.

41. The method of claim 34, wherein the semiconductor substrate is formed of single crystal silicon or polycrystalline silicon.
